(19) United States
(12) Patent Application Publication
(10) Pub. No.: US 2024/0279915 A1
(43) Pub. Date: Aug. 22, 2024

(54) BIDET AND METHOD FOR CONTROLLING SAME

(71) Applicant: COWAY CO., LTD., Gongju-si (KR)

(72) Inventors: Jongwoo KIM, Seoul (KR); Min Hwan KIM, Seoul (KR); Sung Worl JIN, Seoul (KR); Kichul KIM, Seoul (KR); Jinwoo KIM, Seoul (KR)

(73) Assignee: COWAY CO., LTD., Gongju-si (KR)

(21) Appl. No.: 18/571,943

(22) PCT Filed: May 27, 2022
(86) PCT No.: PCT/KR2022/007538

§ 371 Date: Dec. 19, 2023

(30) Foreign Application Priority Data
Jun. 21, 2021 (KR) 10-2021-0080354

(51) Int. Cl. E03D 9/08; G05B 23/02

(52) U.S. Cl. CPC E03D 9/08; G05B 23/0275

(57) ABSTRACT

A bidet comprises: one or more part groups including a plurality of element parts; a control device that diagnoses whether the plurality of element parts included in the one or more part groups operate normally according to a diagnosis mode including a regular diagnosis mode for diagnosing whether the one or more part groups are operating normally when in use by a user and a precise diagnosis mode for diagnosing whether the one or more part groups are operating normally when not in use by the user; a load input unit that applies a predetermined electric load for diagnosis to a part to be diagnosed, which is at least one of the plurality of element parts, in the precise diagnosis mode; and an output sensing unit that senses an electrical output value output from the part to be diagnosed when the electric load for diagnosis is applied.

### TECHNICAL FIELD

The present disclosure relates to a bidet and a method for controlling same.

### BACKGROUND ART

In general, a bidet is a device for washing a user's body that is installed at the top of a toilet bowl. The bidet can clean the user's body by spraying washing water at a predetermined pressure towards the user, and can provide a function of drying the washing water remaining on the user's body.

The bidet may include parts to heat washing water to a predetermined temperature or provide dry air to the user. In addition, parts break down after being used for a certain period of time, and when the part break down, it is difficult for the user to determine which part has failed. In order to resolve such failure of parts, a manager visited and inspected the bidet.

However, when a manager visited, it was difficult to know which part has a problem until the manager personally diagnosed it, and even if the manager visited, it took a lot of time to find the part causing the failure. Accordingly, a bidet that can automatically diagnose the malfunction of the bidet even without a manager visiting.

The present applicant's Korean Patent Application Publication No. 10-2012-0033792 entitled “Self-diagnosis method of indoor device” (Patent Document 1) discloses a self-diagnosis method that can automatically diagnose a malfunction of a bidet. The self-diagnosis method determines whether a part has failed depending on whether the load generated by applying current to the part falls within a reference range.

However, the self-diagnosis method of Patent Document 1 diagnoses failure of parts by applying current to the parts actually used in a specific function when the specific function is input by a user. Since the self-diagnosis method of Patent Document 1 tests only the parts used in the specific function input, it is difficult to test parts that are not actually used in a case where the user uses only the specific function. In addition, in a case where tests are repeatedly performed only on parts that generate excessive heat, certain parts may fail due to overheating. Further, since the self-diagnosis method of Patent Document 1 simultaneously tests parts used in the specific function to determine whether the measured value is within an allowable range, it was difficult to identify a single failed part among the tested parts.

Therefore, there is a need for a bidet that can perform failure diagnosis not only on parts actually used in a specific function but also on other parts, and can accurately determine the failed part by performing tests individually for each part.

### DETAILED DESCRIPTION OF INVENTION

### Technical Problems

One embodiment of the present disclosure is anticipated based on the above background, and provides a bidet capable of performing failure diagnosis not only on parts actually used in a specific function but also on other parts.

Further, one embodiment of the present disclosure provides a bidet capable of preventing excessive heat from being generated in specific parts by performing a test according to a predetermined sequence.

In addition, one embodiment of the present disclosure provides a bidet capable of accurately determining a failed part by individually performing a test for each part.

### Technical Solution

In accordance with one aspect of the present disclosure, there is provided a bidet comprising: one or more part groups including a plurality of component parts: a control device that diagnoses whether the plurality of component parts included in the one or more part groups operate normally according to a diagnosis mode including a regular diagnosis mode for diagnosing whether the one or more part groups operate normally when in use by a user and a precise diagnosis mode for diagnosing whether the one or more part groups operate normally when not in use; a load input unit that applies a predetermined electrical load for diagnosis to at least one diagnostic target part among the plurality of component parts in the precise diagnosis mode: and an output detection unit that detects an electrical output value output from the at least one diagnostic target part when the electrical load for diagnosis is applied, wherein the control device determines the diagnostic target part as abnormal when the electrical output value detected by the output detection unit is out of a pre-input reference output range, and wherein when diagnosing the at least one diagnostic target part communicating with each other in the precise diagnosis mode, according to an order in which heat generated when diagnosing an earlier diagnostic target part that is diagnosed first among the at least one diagnostic target part is removed when diagnosing a later diagnosis target part that is diagnosed later, the control device diagnoses the plurality of diagnostic target parts.

Further, the at least one diagnostic target part may include a drying heater for heating air blown to an outside and a drying fan for controlling flow of the air, the earlier diagnostic target part may be the drying heater, and the later diagnostic target part may be the drying fan.

Further, the at least one diagnostic target part may include a hot water heater for heating water discharged to an outside and a water supply valve for controlling flow of the water, the earlier diagnostic target part may be the hot water heater, and the later diagnostic target part may be the water supply valve.

Further, the at least one diagnostic target part may further include a sterilizing module for supplying a sterilizing substance to the water, and the control device may diagnose the sterilization module after diagnosing the water supply valve in the precise diagnosis mode.

The bidet may further comprise a communication unit that transmits a diagnosis result determined by the control device to a server or a user terminal.

Further, the electrical load for diagnosis may be greater than a usage electrical load applied to the one or more part groups in the regular diagnosis mode.

Further, the reference output range may be input differently for each of the plurality of component parts.

Further, the bidet may further comprise a part operation detection unit including a plurality of part sensors for detecting operation of at least some of the plurality of component parts, wherein the plurality of part sensors may include at least one of a toilet seat temperature sensor, an inlet water temperature sensor, an outlet water temperature sensor, a seating sensor, and a water level detection sensor, the control device may perform a sensor test by applying a predetermined electrical load for sensor test to the part operation detection unit, the output detection unit may further detect an electrical output value when the electrical load for sensor test is applied to the part operation detection unit, and the control device may perform the sensor test by applying the electrical load for sensor test to the plurality of part sensors sequentially, and determining the part sensor to which the electrical load for sensor test is applied as abnormal when the electrical output value detected through the output detection unit is determined to be out of the pre-input reference output range.

In accordance with another aspect of the present disclosure, there is provided a bidet control method for controlling a bidet, the method comprising: a diagnosis step of diagnosing, for one or more part groups including a plurality of component parts, whether the plurality of component parts operate normally according to a diagnosis mode, wherein the diagnosis mode includes a regular diagnosis mode for diagnosing whether the one or more part groups operate normally when a user uses the bidet, and a precise diagnosis mode for diagnosing whether the one or more part groups operate normally when the bidet is not used by a user, the diagnosis step includes: an electrical load application step of applying a predetermined electrical load for diagnosis to at least one diagnostic target part among the plurality of component parts in the precise diagnosis mode: an electrical output value detection step in which an output detection unit detects an electrical output value output from the at least one diagnostic target part when the electrical load for diagnosis is applied; and a normal/abnormal determination step of determining the diagnostic target part as abnormal when the electrical output value detected by the output detection unit is out of a pre-input reference output range, and in the normal/abnormal determination step, when diagnosing the at least one diagnostic target part communicating with each other in the precise diagnosis mode, the plurality of diagnostic target parts are diagnosed according to an order in which heat generated when diagnosing an earlier diagnostic target part that is diagnosed first among the at least one diagnostic target part is removed when diagnosing a later diagnosis target part that is diagnosed later.

Further, the at least one diagnostic target part may include a drying heater for heating air blown to an outside and a drying fan for controlling flow of the air, and in the normal/abnormal determination step, the earlier diagnostic target part may the drying heater, and the later diagnostic target part may be the drying fan.

Further, the at least one diagnostic target part may include a hot water heater for heating water discharged to an outside and a water supply valve for controlling flow of the water, and in the normal/abnormal determination step, the earlier diagnostic target part may be the hot water heater, and the later diagnostic target part may be the water supply valve.

### Effect of Invention

According to one embodiment of the present disclosure, it is possible to perform failure diagnosis not only on parts actually used in a specific function but also on other parts.

Further, according to one embodiment of the present disclosure, it is possible to prevent excessive heat from being generated in specific parts by performing a test according to a predetermined sequence.

In addition, according to one embodiment of the present disclosure, it is possible to accurately determine a failed part by individually performing a test for each part.

### BRIEF DESCRIPTION OF THE DRAWINGS

FIG. 1 is a block diagram conceptually showing a bidet according to one embodiment of the present disclosure.

FIG. 2 is a block diagram conceptually showing the detailed configuration of a part group and a part operation detection unit of FIG. 1.

FIG. 3 is a flow chart sequentially showing a bidet control method for controlling the bidet according to one embodiment of the present disclosure.

### BEST MODE FOR CARRYING OUT THE INVENTION

Hereinafter, specific embodiments for implementing the technical ideas of the present disclosure will be described in detail with reference to the drawings.

In addition, in describing the present disclosure, when it is determined that a detailed description of the relevant known configuration or function may obscure the main idea of the present disclosure, the detailed description thereof will be omitted.

Further, when a component is mentioned to be “transferred” to another component, it should be understood that it may be directly transferred to another component, but there may be other components therebetween.

The terms used in the present specification are used merely to describe the specific embodiments and are not intended to limit the present disclosure. Singular expressions include the plural unless the context clearly indicates otherwise.

Furthermore, the terms containing ordinal numbers, such as first, second, etc., may be used to describe various components, but the components are not limited by such terms. These terms are used only to distinguish one component from another.

The meaning of “include” used in the present specification is intended to specify certain features, areas, integers, steps, operations, elements, and/or components, and is not intended to exclude the existence or the addition of other specific features, areas, integers, steps, operations, elements, components, and/or groups.

Hereinafter, a bidet 1 according to a first embodiment of the present disclosure will be described with reference to the drawings.

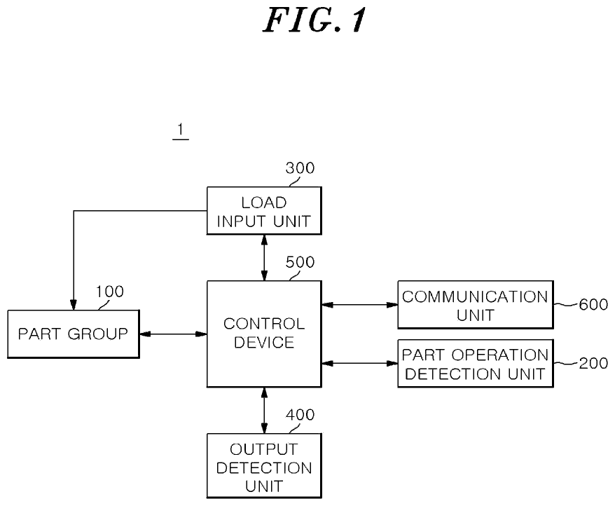

Hereinafter, referring to FIG. 1, the bidet 1 according to one embodiment of the present disclosure may include a plurality of component parts, and the operation of the plurality of component parts may be diagnosed according to a predetermined mode. The bidet 1 can perform a regular diagnosis mode to diagnose whether the plurality of component parts operate normally when a user uses the bidet 1. In addition, the bidet 1 can perform not only a regular diagnosis mode but also a precise diagnosis mode that diagnoses whether one or more part groups operate normally when the bidet 1 is not in use. The bidet 1 may include a part group 100, a part operation detection unit 200, a load input unit 300, an output detection unit 400, a control device 500, and a communication unit 600.

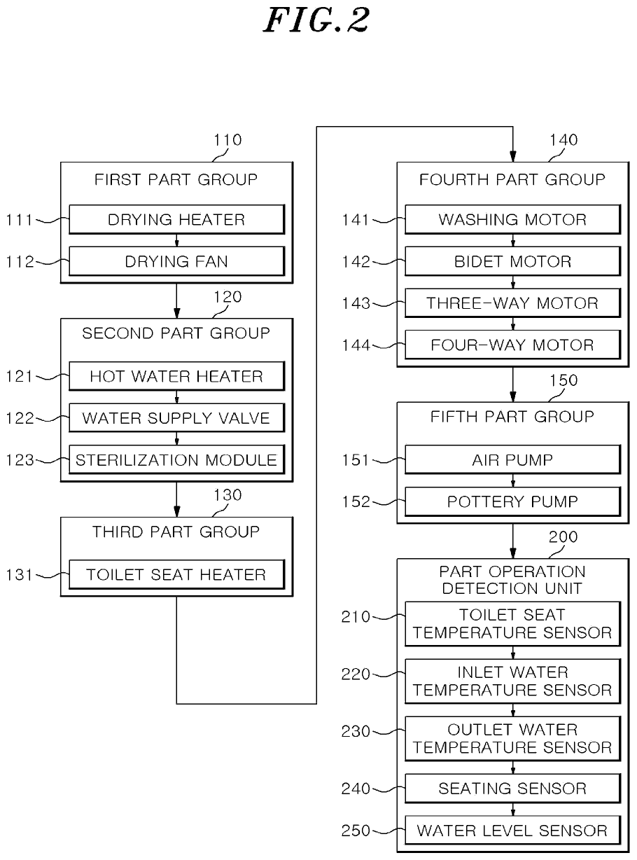

Referring to FIG. 2, the part group 100 may include a plurality of part groups 100. The part group 100 may include a first part group 110, a second part group 120, a third part group 130, a fourth part group 140, and a fifth part group 150.

The first part group 110 may provide a drying function to the user. For example, when washing water is sprayed on the user, the first part group 110 may dry the washing water that remains on the user. The first part group 110 may include a drying heater 111 and a drying fan 112.

The drying heater 111 may heat air blown to the outside of the bidet 1 to provide warm air to the user. In other words, the drying heater 111 may heat the air blown to the outside of the bidet 1 by the drying fan 112. For example, a target temperature of the air heated by the drying heater 111 may be input by the user.

The drying fan 112 may flow air heated by the drying heater 111 to the outside. In addition, the drying fan 112 may control the flow of heated air. The heated air flowing through the drying fan 112 can dry the washing water remaining on the user.

The second part group 120 may control the temperature of the washing water provided to the user. In addition, the second part group 120 may sterilize the washing water provided to the user. The second part group 120 may include a hot water heater 121, a water supply valve 122, and a sterilization module 123.

The hot water heater 121 may adjust the washing water provided to the user to a predetermined temperature. For example, the hot water heater 121 may heat the user to a predetermined temperature so that the user does not feel uncomfortable due to the washing water. The target temperature of the washing water heated by the hot water heater 121 may be input by the user.

The water supply valve 122 may control the flow of washing water flowing inside the bidet 1. For example, the water supply valve 122 may be opened to discharge the washing water heated to a predetermined temperature by the hot water heater 121 to the outside.

The sterilization module 123 may sterilize the washing water flowing inside the bidet 1. For example, the sterilizing module 123 may sterilize the washing water by adding sterilizing powder to the washing water. In this case, the sterilization module 123 may sterilize the washing water flowing outward by the water supply valve 122 because the sterilizing effect increases more when the sterilizing powder is contained in the flowing washing water than in the washing water remaining in a certain space.

The third part group 130 may control the temperature of a toilet seat. The third part group 130 may include a toilet seat heater 131.

The toilet seat heater 131 may be installed on the toilet seat on which a user can sit, and may heat the toilet seat. For example, the toilet seat heater 131 may include a heating wire provided inside the toilet seat, and may heat the toilet seat by supplying power to the heating wire. A target temperature of the toilet seat heated by the toilet seat heater 131 may be input by the user.

The fourth part group 140 may provide power to parts in the bidet 1. The fourth part group 140 may include a washing motor 141, a bidet motor 142, a three-way motor 143, and a four-way motor 144.

The washing motor 141 may move a washing nozzle (not shown) to discharge washing water to the user.

The bidet motor 142 may move a bidet nozzle (not shown) to discharge washing water to the user.

The three-way motor 143 may control a flow rate of fluid flowing inside the bidet 1. In other words, the three-way motor 143 may control the flow rate of the fluid by opening and closing a flow path provided inside the bidet 1.

The four-way motor 144 may control a flow direction of fluid flowing inside the bidet 1. In other words, the four-way motor 144 may change the flow direction of the fluid by opening and closing a flow path provided inside the bidet 1.

The fifth part group 150 may flow water flowing through the bidet 1. The fifth part group 150 may include an air pump 151 and a pottery pump 152.

The air pump 151 may inject air into the washing water flowing through the washing nozzle and the bidet nozzle. The washing water injected with air by the air pump 151 may be discharged to the outside through the washing nozzle and the bidet nozzle.

The pottery pump 152 may flow cleaning liquid for cleaning the inside of the pottery of the bidet 1 to a sterilizing nozzle (not shown).

The part operation detection unit 200 may include a plurality of part sensors that detect the operation of at least some of the plurality of component parts. The plurality of part sensors may include a toilet seat temperature sensor 210, an inlet water temperature sensor 220, an outlet water temperature sensor 230, a seating sensor 240, and a water level sensor 250.

The toilet seat temperature sensor 210 may be provided on the toilet seat to measure a temperature of the toilet seat. The temperature of the toilet seat measured by the toilet seat temperature sensor 210 may be transmitted to the toilet seat heater 131.

The inlet water temperature sensor 220 may measure a temperature of water supplied to the bidet 1. The inlet water temperature sensor 220 may transmit the measured temperature of the water to the control device 500.

The outlet water temperature sensor 230 may measure a temperature of water discharged from the bidet 1 to the outside. The outlet water temperature sensor 230 may transmit the measured temperature of water to the control device 500.

The seating sensor 240 may detect whether a user is sitting on the toilet seat. For example, the seating sensor 240 may generate a signal when a user sits on the toilet seat, and may transmit the generated signal to the control device 500.

The water level sensor 250 may measure a water level in the toilet bowl. The water level sensor 250 may transmit the measured water level in the toilet bowl to the control device 500.

The load input unit 300 may apply a predetermined electrical load for diagnosis to a diagnostic target part in the precise diagnosis mode. In this case, the diagnostic target part refers to a part that is subject to diagnosis to which an electrical load will be applied by the load input unit 300 among a plurality of component parts, and may be at least one of the plurality of component parts. The load input unit 300 may measure the electrical load for diagnosis applied to the diagnostic target part. For example, when applying the electrical load for diagnosis to the diagnostic target part, the load input unit 300 may measure a current of AC load applied through a current transformer (CT). In addition, the load input unit 300 may measure a current of DC load applied through a shunt resistor when applying the electrical load for diagnosis to the diagnostic target part. Meanwhile, the load input unit 300 may apply an electrical load for diagnosis greater than the usage electrical load applied to one or more part groups 100 in the regular diagnosis mode to the diagnostic target part in the precise diagnosis mode.

In addition, the load input unit 300 may apply a predetermined electrical load for sensor test to the part operation detection unit 200. For example, the load input unit 300 may apply an electrical load for sensor test to the part operation detection unit 200 in the same manner as the electrical load for diagnosis is applied to the diagnostic target part. However, the electrical load for sensor test may have a different magnitude from that of the electrical load for diagnosis.

The output detection unit 400 may detect an electrical output value output from the diagnostic target part when an electrical load for diagnosis is applied to the diagnostic target part. For example, the output detection unit 400 may measure an AC load output from the diagnostic target part as high current and low current using Op-AMP. In addition, the output detection unit 400 may measure a DC current output from the diagnostic target part as high current and low current using Op-AMP. Further, when an electrical load for sensor test is applied to the part operation detection unit 200, the output detection unit 400 may detect an electrical output value from the part sensor to which the electrical load for the sensor test has been applied.

The control device 500 may diagnose whether a plurality of component parts included in one or more parts groups 100 operate normally according to the diagnosis mode. In this case, the diagnosis mode may include the regular diagnosis mode and the precise diagnosis mode described above. When one of the plurality of part groups 100 is used in the regular diagnosis mode, the control device 500 may determine whether the usage part group 100 operates normally. In addition, the control device 500 may also perform the regular diagnosis mode at a predetermined cycle.

The control device 500 may determine whether the plurality of part groups 100 operate normally in the precise diagnosis mode. The control device 500 may sequentially diagnose a plurality of diagnostic target parts in fluid communication with each other in a diagnosis order. In this case, the control device 500 may perform the diagnosis according to a diagnosis order in which the heat generated when diagnosing an earlier diagnosis target part that is diagnosed first among the plurality of diagnosis target parts can be removed when diagnosing a later diagnosis target part, and the diagnosis order may be determined by the control device 500 or may be predetermined depending on the diagnosis mode.

For example, when the control device 500 determines whether the first part group 110 operates normally, the control device 500 may diagnose the drying heater 111 as the earlier diagnosis target part and the dry fan 112 as the later diagnosis target part. In this case, heat generated from the drying heater 111 during the process of diagnosing the drying heater 111 may be cooled by the operation of the drying fan 112 during the process of diagnosing the drying fan 112.

Accordingly, it is possible to prevent parts from being damaged by the heat generated by the drying heater 111, and the heat can be naturally removed during the process of diagnosing the drying fan 112.

As another example, when the control device 500 determines whether the second part group 120 operates normally, the control device 500 may diagnose the hot water heater 121 as the earlier diagnosis target part, and the water supply valve 122 as the later diagnosis target part. In this case, water heated during the process of diagnosing the hot water heater 121 may be discharged to the outside during the process of diagnosing the water supply valve 122. In addition, the control device 500 may determine the sterilization module 123 as a part to be diagnosed later than the water supply valve 122 and diagnose the sterilization module 123 after diagnosing the water supply valve 122.

Accordingly, it is possible to prevent high-temperature water generated by the hot water heater 121 from being discharged directly to the user, and the high-temperature water can be naturally removed during the process of diagnosing the water supply valve 122. In addition, the sterilization effect can be improved by operating the sterilizing module 123 in the process of discharging water through the water supply valve 122 to add sterilizing powder to the flowing water.

As another example, when the control device 500 determines whether the fourth part group 140 operates normally, the washing motor 141, the bidet motor 142, the three-way motor 143, and the four-way motor 144 may be diagnosed sequentially. In addition, when the control device 500 determines whether the fifth part group 150 operates normally, the air pump 151 and the pottery pump 152 can be sequentially diagnosed. However, this does not limit the present disclosure, and the order of diagnosing parts may be changed depending on the case.

The control device 500 may determine that the diagnostic target part is abnormal when the electrical output value detected by the output detection unit 400 is out of a pre-input reference output range. For example, the reference output range previously input to the control device 500 may be input differently for each of the plurality of component parts. That is, the parts of the first part group 110 and the parts of the second part group 120 may have different reference output ranges. In addition, the control device 500 may transmit the determined diagnosis result to the communication unit 600. The control device 500 may be implemented by a computing device including a microprocessor, a measuring device such as a sensor, and a memory, and since the implementation method is obvious to those skilled in the art, detailed description thereof will be omitted.

Meanwhile, the control device 500 may control the load input unit 300 to sequentially apply an electrical load for sensor test to the plurality of element sensors. In addition, the control device 500 may sequentially perform sensor tests on the plurality of element sensors. For example, the control device 500 may sequentially perform sensor tests on the toilet seat temperature sensor 210, the inlet water temperature sensor 220, the outlet water temperature sensor 230, the seating sensor 240, and the water level detection sensor 250. When the electrical output value detected through the output detection unit 400 during the sensor test process is out of the pre-input reference output range, the control device 500 may determine that the element sensor to which the electrical load for sensor test has been applied is abnormal.

In FIG. 2, the control device 500 is shown to diagnose the part operation detection unit 200 after the part group 100 has been diagnosed, but this is only an example and does not limit the present disclosure. Thus, the diagnosis of the part operation detection unit 200 may be performed before diagnosing the part group 100, and may also be performed between the diagnosis of the first part group 110 and the second part group 120.

The communication unit 600 may transmit the diagnosis result determined by the control device 500 to a server (not shown) or a user terminal (not shown). For example, the user terminal may be a mobile phone, PDA, or tablet. The communication unit 600 may transmit and receive data to and from the server or user terminal by wired or wireless means. For example, when the communication unit 600 transmits and receives data wirelessly, the communication unit 600 may operate in any one of Wi-Fi, Bluetooth, Near Field Communication (NFC), Radio Frequency (RF), and infrared communication.

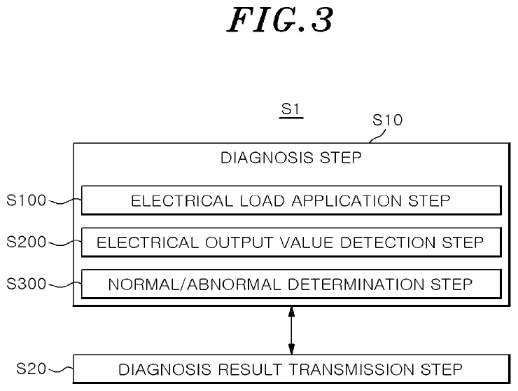

Hereinafter, a bidet control method S1 for controlling the bidet 1 according to one embodiment of the present disclosure will be described with reference to FIG. 3.

The bidet control method S1 may perform diagnosis according to a predetermined mode to determine whether a plurality of component parts included in the bidet 1 operate normally. The bidet control method S1 may include a diagnosis step S10 and a diagnosis result transmission step S20.

In the diagnosis step S10, whether the plurality of component parts operates normally according to a diagnosis mode for one or more part groups may be diagnosed. The diagnosis step S10 may include an electrical load application step S100, an electrical output value detection step S200, and a normal/abnormal determination step S300.

In the electrical load application step S100, the load input unit 300 may apply a predetermined electrical load for diagnosis to the diagnostic target part in the precise diagnosis mode. In addition, in the electrical load application step S100, the load input unit 300 may apply an electrical load for sensor test to the part operation detection unit 200.

In the electrical output value detection step S200, when an electrical load for diagnosis is applied, the output detection unit 400 may detect the electrical output value output from the diagnostic target part. In addition, in the electrical output value detection step S200, when an electrical load for sensor test is applied, the output detection unit 400 may detect the electrical output value output from the part operation detection unit 200.

In the normal/abnormal determination step S300, a plurality of diagnostic target parts may be sequentially diagnosed according to a diagnosis order. In the normal/abnormal determination step S300, when the electrical output value detected by the output detection unit 400 is out of the pre-input reference output range, the diagnostic target part may be determined as abnormal.

In addition, in the normal/abnormal determination step S300, when diagnosing a plurality of diagnostic target parts that are in fluid communication with each other in the precision diagnosis mode, the diagnosis is performed in the diagnosis order in which the heat generated when diagnosing the earlier diagnostic target part to be diagnosed first can be removed when diagnosing the later diagnostic target part to be diagnosed later. The diagnosis order may be determined by the control device 500 or may be predetermined depending on the diagnosis mode.

In the diagnosis result transmission step S20, the communication unit 600 may transmit the diagnosis result determined in the diagnosis step S10 to the server or user terminal.

The embodiments of the present disclosure have been described above as specific embodiments, but these are only examples. The present disclosure is not limited thereto, and should be construed as having the widest scope according to the technical idea disclosed in the present specification. A person skilled in the art may combine/substitute the disclosed embodiments to implement a pattern of a shape that is not disclosed, but it also does not depart from the scope of the present disclosure. In addition, those skilled in the art can easily change or modify the disclosed embodiments based on the present specification, and it is clear that such changes or modifications also belong to the scope of the present disclosure.

What is claimed is:

1. A bidet comprising:
one or more part groups including a plurality of component parts:
a control device that diagnoses whether the plurality of component parts included in the one or more part groups operate normally according to a diagnosis mode including a regular diagnosis mode for diagnosing whether the one or more part groups operate normally when in use by a user and a precise diagnosis mode for diagnosing whether the one or more part groups operate normally when not in use:
a load input unit that applies a predetermined electrical load for diagnosis to at least one diagnostic target part among the plurality of component parts in the precise diagnosis mode: and
an output detection unit that detects an electrical output value output from the at least one diagnostic target part when the electrical load for diagnosis is applied,
wherein the control device determines the diagnostic target part as abnormal when the electrical output value detected by the output detection unit is out of a pre-input reference output range, and
wherein when diagnosing the at least one diagnostic target part communicating with each other in the precise diagnosis mode, according to an order in which heat generated when diagnosing an earlier diagnostic target part that is diagnosed first among the at least one diagnostic target part is removed when diagnosing a later diagnosis target part that is diagnosed later, the control device diagnoses the plurality of diagnostic target parts.

2. The bidet of claim 1, wherein the at least one diagnostic target part includes a drying heater for heating air blown to an outside and a drying fan for controlling flow of the air,
the earlier diagnostic target part is the drying heater, and
the later diagnostic target part is the drying fan.

3. The bidet of claim 1, wherein the at least one diagnostic target part includes a hot water heater for heating water discharged to an outside and a water supply valve for controlling flow of the water,
the earlier diagnostic target part is the hot water heater, and
the later diagnostic target part is the water supply valve.

4. The bidet of claim 3, wherein the at least one diagnostic target part further includes a sterilizing module for supplying a sterilizing substance to the water, and
the control device diagnoses the sterilization module after diagnosing the water supply valve in the precise diagnosis mode.

5. The bidet of claim 1, further comprising:
a communication unit that transmits a diagnosis result determined by the control device to a server or a user terminal.

6. The bidet of claim 1, wherein the electrical load for diagnosis is greater than a usage electrical load applied to the one or more part groups in the regular diagnosis mode.

7. The bidet of claim 1, wherein the reference output range is input differently for each of the plurality of component parts

8. The bidet of claim 1, further comprising a part operation detection unit including a plurality of part sensors for detecting operation of at least some of the plurality of component parts,
wherein the plurality of part sensors include at least one of a toilet seat temperature sensor, an inlet water temperature sensor, an outlet water temperature sensor, a seating sensor, and a water level detection sensor,
the control device performs a sensor test by applying a predetermined electrical load for sensor test to the part operation detection unit,
the output detection unit further detects an electrical output value when the electrical load for sensor test is applied to the part operation detection unit, and
the control device performs the sensor test by applying the electrical load for sensor test to the plurality of part sensors sequentially, and determining the part sensor to which the electrical load for sensor test is applied as abnormal when the electrical output value detected through the output detection unit is determined to be out of the pre-input reference output range.

9. A bidet control method for controlling a bidet, the method comprising:
a diagnosis step of diagnosing, for one or more part groups including a plurality of component parts, whether the plurality of component parts operate normally according to a diagnosis mode,
wherein the diagnosis mode includes a regular diagnosis mode for diagnosing whether the one or more part groups operate normally when a user uses the bidet, and a precise diagnosis mode for diagnosing whether the one or more part groups operate normally when the bidet is not used by a user,
wherein the diagnosis step includes:
an electrical load application step of applying a predetermined electrical load for diagnosis to at least one diagnostic target part among the plurality of component parts in the precise diagnosis mode:
an electrical output value detection step in which an output detection unit detects an electrical output value output from the at least one diagnostic target part when the electrical load for diagnosis is applied: and
a normal/abnormal determination step of determining the diagnostic target part as abnormal when the electrical output value detected by the output detection unit is out of a pre-input reference output range, and
wherein in the normal/abnormal determination step, when diagnosing the at least one diagnostic target part communicating with each other in the precise diagnosis mode, the plurality of diagnostic target parts are diagnosed according to an order in which heat generated when diagnosing an earlier diagnostic target part that is diagnosed first among the at least one diagnostic target part is removed when diagnosing a later diagnosis target part that is diagnosed later.

10. The bidet control method of claim 9, wherein the at least one diagnostic target part includes a drying heater for heating air blown to an outside and a drying fan for controlling flow of the air, and
wherein in the normal/abnormal determination step, the earlier diagnostic target part is the drying heater, and the later diagnostic target part is the drying fan.

11. The bidet control method of claim 9, wherein the at least one diagnostic target part includes a hot water heater for heating water discharged to an outside and a water supply valve for controlling flow of the water, and
wherein in the normal/abnormal determination step, the earlier diagnostic target part is the hot water heater, and the later diagnostic target part is the water supply valve.
